(19) United States
(12) Patent Application Publication
(10) Pub. No.: US 2007/0216030 A1
(43) Pub. Date: Sep. 20, 2007

(54) INTEGRATED CIRCUIT HAVING A MULTILAYER CAPACITANCE ARRANGEMENT

(75) Inventors: Guenther Schindler, Muenchen (DE); Eugen Unger, Augsburg (DE); Wolfgang Hoenlein, Unterhaching (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Muenchen (DE)

(21) Appl. No.: 11/675,400

(22) Filed: Feb. 15, 2007

(30) Foreign Application Priority Data
Feb. 16, 2006 (DE) 10 2006 007 331.2

(51) Int. Cl. H01L 23/48

(52) U.S. Cl. 257/763

(57) ABSTRACT

An integrated circuit having a multilayer capacitance arrangement and a method for producing an integrated circuit having a multilayer capacitance arrangement are disclosed.

### CROSS-REFERENCE TO RELATED APPLICATIONS

This Utility Patent Application claims priority to German Patent Application No. DE 10 2006 007 331.2 filed on Feb. 16, 2006, which is incorporated herein by reference.

### BACKGROUND

The invention relates generally to multilayer capacitance arrangements.

Multilayer capacitance arrangements or MIM (metal-insulator-metal) capacitances are layer arrangements composed of two electrically conductive layers/plates and an insulating interlayer arranged in between which have the capability of storing electrical charge.

It is desirable to provide multilayer capacitance arrangements for use or application in integrated circuits which have a comparatively small space requirement even in the case of very large capacitances.

For these and other reasons, there is a need for the present invention.

### SUMMARY

One embodiment provides an integrated circuit having a multilayer capacitor arrangement having a substrate with electronic components integrated therein. At least one metallization level arranged above the substrate and having interconnects for connecting the electronic components is provided. In one embodiment a first electrically conductive layer is provided above the at least one metallization level, and a first dielectric layer is provided on or above the first electrically conductive layer. In one embodiment, a second electrically conductive layer is provided on or above the first dielectric layer, a second dielectric layer on or above the second electrically conductive layer; and a third electrically conductive layer is provided on or above the second dielectric layer.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a layer sequence at a first point in time during a method for producing a multilayer capacitance arrangement in one embodiment of the invention.

FIG. 2 illustrates a layer sequence at a second point in time during the method for producing a multilayer capacitance arrangement in accordance with one embodiment of the invention.

FIG. 3 illustrates a layer sequence at a third point in time during the method for producing a multilayer capacitance arrangement in accordance with one embodiment of the invention.

FIG. 4 illustrates a layer sequence at a fourth point in time during the method for producing a multilayer capacitance arrangement in accordance with one embodiment of the invention.

FIG. 5 illustrates a layer sequence at a fifth point in time during the method for producing a multilayer capacitance arrangement in accordance with one embodiment of the invention.

FIG. 6 illustrates a layer sequence at a sixth point in time during the method for producing a multilayer capacitance arrangement in accordance with one embodiment of the invention.

FIG. 7 illustrates a layer sequence at a seventh point in time during the method for producing a multilayer capacitance arrangement in accordance with one embodiment of the invention.

FIG. 8 illustrates a layer sequence at an eighth point in time during the method for producing a multilayer capacitance arrangement in accordance with one embodiment of the invention.

FIG. 9 illustrates a multilayer capacitance arrangement produced in accordance with one embodiment of the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Multilayer capacitance arrangements or MIM (metal-insulator-metal) capacitances are layer arrangements composed of two electrically conductive layers/plates and an insulating interlayer arranged in between which have the capability of storing electrical charge.

The quantity of electrical charge which can be stored by an MIM capacitance (=capacitor) for a given voltage applied to the two electrically conductive plates is dependent, inter alia, on the size/area of the two electrically conductive plates and the distance between the two electrically conductive plates, the capacity or the capacitance (=quantity of charge Q/applied voltage U) of a capacitor increasing as the plate area increases and the distance between the plates decreases. Consequently, the size of the electrically conductive plates and hence the basic area occupied by the MIM capacitance increase considerably with increasing capacitance requirements.

For the application of MIM capacitances in integrated circuits (IC), such as e.g., for radio frequency applications, this means that the MIM capacitances have a considerable space requirement (=area proportion relative to the chip basic area) within the integrated circuits.

One conventional method for increasing the capacitance or for reducing the basic area occupied by MIM capacitances in integrated circuits with the capacitance remaining the same consists in the use of high-k dielectrics, such as e.g., Al₂O₃, for the insulating interlayer. However, the area proportion relative to the total chip basic area can be reduced only to a limited extent by this means. The increased space requirement of the MIM capacitances in integrated circuits has otherwise had to be accepted heretofore, or a compromise found between capacitance and space requirement.

A multilayer capacitance arrangement in accordance with one embodiment has a substrate with electronic components integrated therein, at least one metallization level arranged above the substrate and having interconnects for connecting the electronic components, a first electrically conductive layer above the at least one metallization level, a first dielectric layer on or above the first electrically conductive layer, a second electrically conductive layer on or above the first dielectric layer, a second dielectric layer on or above the second electrically conductive layer and a third electrically conductive layer on or above the second dielectric layer.

In one embodiment, the problem of the large space requirement (=basic area of the capacitance arrangement relative to the chip basic area) of the MIM capacitances in integrated circuits is solved by the provision of (at least) three electrically conductive plates/layers that are arranged one above another and are insulated from one another. For a given capacitance of the arrangement, the area of the layers or the basic area of the arrangement and hence the space requirement of the arrangement can be considerably reduced by this means. On the basis of the MIM capacitances used heretofore in integrated circuits, it is possible, in one embodiment, to provide (at least) one additional electrically conductive layer in the vertical direction, whereby a reduction of the space requirement and an increase in the capacitance are simultaneously achieved.

In another embodiment, a multilayer capacitance arrangement can be extended in the vertical direction by as many electrically conductive layers insulated from one another as desired. The provision of more than three electrically conductive layers one above another enables the capacitance of the arrangement to be increased further and/or the space requirement of the arrangement to be reduced further, with the result that the ratio of capacitance and basic area of the arrangement (=area utilization) continuously rises as the number of electrically conductive layers increases.

In another embodiment, the first dielectric layer and the second dielectric layer are in each case composed of a high-k dielectric or of SiO₂, in which case the use of a high-k dielectric enables the capacitance of the arrangement to be increased further with the size of the basic area remaining the same.

In the case of a multilayer capacitance arrangement having more than three electrically conductive layers and having in each case a dielectric layer between two electrically conductive layers, it is possible, in another embodiment, by way of example, for all the dielectric layers to be composed of a high-k dielectric or of silicon dioxide (SiO₂). In another embodiment, the multilayer capacitance arrangement has a first electrically conductive connection element and a second electrically conductive connection element, wherein the first electrically conductive connection element is electrically connected to the first electrically conductive layer and the third electrically conductive layer, and wherein the second electrically conductive connection element is electrically connected to the second electrically conductive layer. In this case, the first electrically conductive connection element is insulated from the second electrically conductive layer and the second electrically conductive connection element is insulated from the first electrically conductive layer and the third electrically conductive layer.

By the first electrically conductive connection element and the second electrically conductive connection element, the electrically conductive layers or plates can be connected to a voltage source, wherein the first electrically conductive layer and the third electrically conductive layer are connected to a first electrical reference potential by the first electrically conductive connection element and the second electrically conductive layer is connected to a second electrical reference potential by the second electrically conductive connection element. The electrically conductive layers can thereby be charged differently, with the result that, by way of example, the first electrically conductive layer and the third electrically conductive layer in each case form a negative electrode and the second electrically conductive layer forms a positive electrode arranged in between.

In the case of a multilayer capacitance arrangement having more than three electrically conductive layers, in another embodiment, by way of example, the layers can be connected alternately to the first electrical reference potential and the second electrical reference potential by the first electrically conductive connection element and the second electrically conductive connection element, respectively. By virtue of the alternative connection of the electrically conductive layers to a first electrical reference potential and a second electrical reference potential, the electrically conductive layers can be charged negatively or positively depending on the respective electrical reference potential to which they are connected, whereby a stack sequence having alternately a positive electrode and a negative electrode can be formed.

In another embodiment, it is provided that the first electrically conductive connection element and the second electrically conductive connection element are formed in such a way that they in each case extend perpendicular to at least one portion of the electrically conductive layers.

In another embodiment, the first electrically conductive connection element may be a second trench filled with electrically conductive material and the second electrically conductive connection element may be a first trench filled with electrically conductive material.

In another embodiment, it is provided that the first electrically conductive connection element extends through the electrically conductive layers at a first position or is arranged alongside the electrically conductive layers at a first position, and that the second electrically conductive connection element extends through the electrically conductive layers at a second position or is arranged alongside the electrically conductive layers at a second position. In this way, the electrically conductive layers can be connected/contact-connected to the first electrically conductive connection element and respectively the second electrically conductive connection element in a particularly simple manner.

In another embodiment, the first electrically conductive layer is produced from a first material, the second electrically conductive layer is produced from a second material and the third electrically conductive layer is produced from the first material, wherein the first and the second material are different.

In the case of a multilayer capacitance arrangement having more than three electrically conductive layers, it is possible, in another embodiment, to arrange an electrically conductive layer composed of the first material and an electrically conductive layer composed of the second material with in each case a dielectric layer arranged in between, one above another.

The use of two different materials for the electrically conductive layers enables all of the layers composed of one material to be processed/patterned, by a method specific/selective for this material, simultaneously in one process selectively with respect to the layers composed of the other material, whereas the structure of the layers composed of the other material remains unchanged during processing. It is thereby possible to pattern a multilayer capacitance arrangement for the alternate/selective connection of the electrically conductive layers to a first electrical reference potential and a second electrical reference potential cost- and time-efficiently, i.e., with a small number of processes.

In another embodiment, it is provided that the first material and the second material can be etched selectively with respect to one another and/or can be oxidized selectively with respect to one another. In this case, one of the first material and the second material may be C (carbon) and the other of the first material and the second material may be Cr (chromium) or Ti (titanium) or Al (aluminum). As an alternative, one of the first material and the second material may be Al (aluminum) and the other of the first material and the second material may be Ni (nickel) or Co (cobalt) or Cu (copper). Furthermore, one of the first material and the second material may be Ti (titanium) and the other of the first material and the second material may be Pd (palladium) or Ni (nickel) or Co (cobalt) or Cu (copper) or Cr (chromium).

If the first material and the second material can be etched selectively with respect to one another, then it is possible, in another embodiment, for the electrically conductive layers composed of the first material and the electrically conductive layers composed of the second material to be processed/patterned selectively with respect to one another with the aid of conventional etching methods particularly simply and efficiently in one work process in each case, with the result that the abovementioned advantages with regard to the patterning of the electrically conductive layers or the multilayer capacitance arrangement are even more clearly pronounced.

In another embodiment, the electrically conductive layers composed of the first material and the electrically conductive layers composed of the second material can be patterned selectively with respect to one another by in each case being selectively oxidized with respect to one another, wherein the oxide produced (=sacrificial oxide) is removed/etched selectively with respect to the non-oxidized material in a respective subsequent method process. The selective oxidation of the electrically conductive layers composed of the first material and of the electrically conductive layers composed of the second material may be effected for example by way of the setting of the oxygen concentration or the oxygen pressure and/or the temperature.

In another embodiment, a method for producing a multilayer capacitance arrangement is provided, in which a first electrically conductive layer is formed above at least one metallization level arranged above a substrate with electronic components integrated therein and having interconnects for connecting the electronic components, a first dielectric layer is formed on or above the first electrically conductive layer, a second electrically conductive layer is formed on or above the first dielectric layer, a second dielectric layer is formed on or above the second electrically conductive layer and a third electrically conductive layer is formed on or above the second dielectric layer.

In another embodiment, firstly a dielectric or insulation layer is deposited/formed on or above the at least one metallization level and the first electrically conductive layer is deposited/formed on or above the insulation layer. In another embodiment, provision is made for providing the electrically conductive layers insulated from one another between two metallization levels.

In another embodiment, the first electrically conductive layer and the third electrically conductive layer can be connected to a first electrical reference potential and the second electrically conductive layer can be connected to a second electrical reference potential. In another embodiment, a first electrically conductive connection element may be formed for the connection of the first electrically conductive layer and the third electrically conductive layer to the first electrical reference potential, and a second electrically conductive connection element may be formed for the connection of the second electrically conductive layer to the second electrical reference potential.

In another embodiment, for the production of the multilayer capacitance arrangement, for example a first material is used for the first electrically conductive layer, for example a second material, which is different than the first material, is used for the second electrically conductive layer and for example the first material is used for the third electrically conductive layer. In this case, the first material and the second material are for example selected in such a way that the first material and the second material can be etched selectively with respect to one another and/or the first material and the second material can be oxidized selectively with respect to one another.

In another embodiment, it is provided, for example, that a hard mask is formed on or above the third electrically conductive layer, the hard mask is patterned, a first trench and a second trench are etched through the electrically conductive layers by the patterned hard mask, the first material is etched selectively with respect to the second material, wherein the first electrically conductive layer and the third electrically conductive layer are etched back laterally proceeding from the first trench, the second material is etched selectively with respect to the first material, wherein the second electrically conductive layer is etched back laterally proceeding from the second trench, the etched-back regions of the electrically conductive layers are at least partly filled with a filling dielectric and electrically conductive material is introduced into the first trench and the second trench. In this case, it is possible to pattern the hard mask firstly only at a first position and to uncover firstly only the first trench, thereby avoiding, in a simple manner, the situation where the etching solution for the selective etching of the first material (of the first electrically conductive layer and of the third electrically conductive layer) penetrates into the second trench, in which later the first connection element for contact-connecting the layers composed of the first material is formed. Afterward, the etched-back regions of the electrically conductive layers composed of the first material can be at least partly filled with the filling dielectric. For this purpose, the first trench can be filled for example completely with filling dielectric. The hard mask can be patterned at a second position, the second trench can be etched free and the second material can be etched selectively with respect to the first material proceeding from the second trench. If the first trench was previously filled completely with the filling dielectric, then the selective etching back of the layers composed of the second material, proceeding from the second trench, may for example be effected by feeding the etching solution for the selective etching of the second material onto the hard mask over an extensive area in a simple manner. In addition, by completely filling the first trench with filling dielectric, it can be ensured that the layers composed of the second material are exclusively etched back proceeding from the second trench and are not additionally etched back proceeding from the first trench, in which later the second connection element for contact-connecting the second layers is formed. The etched-back regions of the layers composed of the second material can be at least partly filled with the filling dielectric. If the first trench was previously filled completely with filling dielectric, the first trench can then be uncovered again in such a way that the filling dielectric is at least partly maintained in the previously etched-back regions of the layers composed of the first material. Afterward, electrically conductive material can be introduced into the first trench and the second trench in order to form the second and the first connection element, respectively.

In another embodiment, prior to the formation of the hard mask, optionally a further dielectric layer may be deposited on or above the third electrically conductive layer as protection and insulation layer, on which the hard mask is then formed.

In another embodiment, the at least partial filling of the etched-back regions is effected for example by introducing the filling dielectric into in each case the first trench and the second trench and also into the respective etched-back regions of the electrically conductive layers in such a way that, in the etched-back regions, at least the region directly adjoining the electrically conductive layer is filled with the filling dielectric, and uncovering the first trench and the second trench again by etching in such a way that, within the etched-back regions, the filling dielectric is maintained at least in the region directly adjoining the electrically conductive layer.

In another embodiment, titanium may be used for one of the first material and the second material and palladium or nickel or cobalt or copper or chromium may be used for the other of the first material and the second material, wherein it is provided, for example, that titanium is etched selectively with respect to the corresponding other material by hydrofluoric acid, and palladium is etched selectively with respect to titanium by nitric acid, nickel, cobalt or copper is etched selectively with respect to titanium by a solution containing peroxodisulfate ions and chromium is etched selectively with respect to titanium by a cerium(IV) solution. In another embodiment, aluminum may be used for one of the first material and the second material and nickel or cobalt or copper may be used for the other of the first material and the second material, wherein it is provided, for example, that aluminum is etched selectively with respect to the corresponding other material by a solution containing hydroxide ions and nickel, cobalt or copper is etched selectively with respect to aluminum by a solution containing peroxodisulfate ions. Furthermore, as an alternative, in another embodiment, carbon may be used for one of the first material and the second material and chromium or titanium or aluminum may be used for the other of the first material and the second material, wherein it is provided, for example, that carbon is etched selectively with respect to the corresponding other material by an O₂ plasma, and chromium is etched selectively with respect to carbon by a cerium(IV) solution, titanium is etched selectively with respect to carbon by hydrofluoric acid and aluminum is etched selectively with respect to carbon by a solution containing hydroxide ions.

In another embodiment, by a method for producing a multilayer capacitance arrangement, a possibility is afforded of producing a multilayer capacitance arrangement particularly economically and providing it with a structure for alternately connecting the electrically conductive layers to a first electrical reference potential and a second electrical reference potential. This is achieved, for example, by the use of different materials for the electrically conductive layers, whereby the possibility/prerequisite is afforded that the layers can be patterned/etched selectively with respect to one another, by etching trenches/vias through the electrically conductive layers in order to pattern the electrically conductive layers proceeding from the trenches and to use the trenches/vias for electrically contact-connecting the layers. In this case, the method in one embodiment is , for example, when a large capacitance relative to the basic area of the arrangement or to the chip basic area is required, i.e., the number of electrically conductive layers is large.

In another embodiment, prior to the formation of the first dielectric layer, the first electrically conductive layer can be patterned and filling dielectric can be introduced into the structure produced in the first electrically conductive layer, and prior to the formation of the second dielectric layer, the second electrically conductive layer can be patterned and filling dielectric can be introduced into the structure produced in the second electrically conductive layer, and after the formation of the third electrically conductive layer, the latter can be patterned and filling dielectric can be introduced into the structure produced in the third electrically conductive layer, wherein provision is made, in one embodiment, for example, for patterning the first electrically conductive layer and the third electrically conductive layer by etching away at a first position a region of the first electrically conductive layer and of the third electrically conductive layer, respectively, which region adjoins the peripheral side of the first electrically conductive layer and of the third electrically conductive layer, respectively, and for patterning the second electrically conductive layer by etching away at a second position a region of the second electrically conductive layer, which region adjoins the peripheral side of the second electrically conductive layer. Furthermore, in one embodiment, provision is made, for example, for connecting the first electrically conductive layer and the third electrically conductive layer to a first reference potential by formation of a first connection element alongside the electrically conductive layers at the second position and for connecting the second electrically conductive layer to a second reference potential by formation of a second connection element alongside the electrically conductive layers at the first position.

In contrast to a method in one embodiment, in which the patterning of the electrically conductive layers is effected after the formation of the electrically conductive layers in two selective etching processes, in the case of a method in another embodiment, the electrically conductive layers are in each case patterned separately directly after their formation. The method in another embodiment is therefore suitable for example for producing and patterning a multilayer capacitance arrangement having a small number of electrically conductive layers, since the number of method processes for patterning the electrically conductive layers rises continuously with the number thereof. Only one material component and only one etching solution are used in the case of the method in another embodiment.

In another embodiment, a multilayer capacitance arrangement is provided for use or application in integrated circuits, which multilayer capacitance arrangement has a comparatively small space requirement (compared with conventional MIM capacitances, for example) even in the case of very large capacitances. In another embodiment, a method for producing such a multilayer capacitance arrangement is provided.

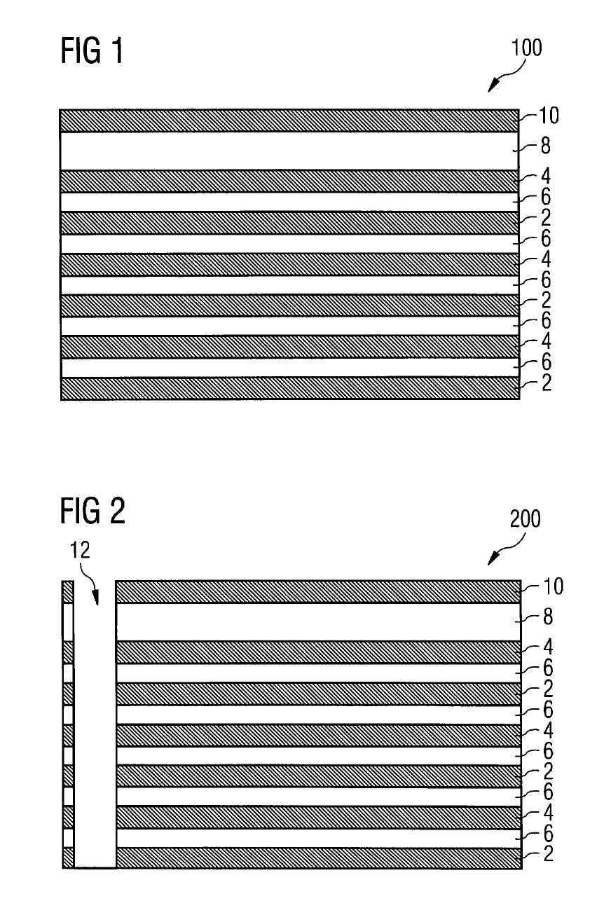

A description is given below, referring to FIG. 1 to FIG. 9, of layer sequences at different points in time during a method for producing a multilayer capacitance arrangement in with one embodiment.

The layer sequences illustrated in FIG. 1 to FIG. 9 are in each case arranged on or above at least one metallization level (not illustrated) of an integrated circuit, the metallization level being arranged above a substrate (not illustrated), and are for example in each case formed/provided on an optional dielectric or insulation layer (not illustrated) which is formed on or above the at least one metallization level (not illustrated).

In order to obtain the layer sequence 100 illustrated in FIG. 1, in one embodiment, in a first method process, on or above the at least one metallization level, alternately an electrically conductive layer composed of a first material 2 and an electrically conductive layer composed of a second material 4 with in each case a dielectric layer 6 between two electrically conductive layers are formed or deposited one above another. The first material 2 and the second material 4 are different materials in one exemplary embodiment. According to the invention, the layer sequence 100 has at least three electrically conductive layers (here: two layers composed of the first material 2 and one layer composed of the second material 4). The number of electrically conductive layers depends for example on the required capacitance of the arrangement and/or the available basic area within the integrated circuit.

In one embodiment, the first material 2 and the second material 4 are selected in such a way that they can be processed or patterned selectively with respect to one another, in particular etched selectively with respect to one another, by a specific method. This has the advantage that in the subsequent method processes, all layers composed of one of the first material 2 and the second material 4 can be patterned simultaneously in only one method process, whereas the layers composed of the other of the first material 2 and the second material 4 are not attacked/patterned in this method process. Possible material pairings of in each case two materials which can be etched selectively with respect to one another and the etchant to be used in each case are illustrated in table 1.

TABLE 1
Possible material pairings and etchants

| Material 1 | | Material 2 | |
|---|---|---|---|
| (Material 2) | Etchant | (Material 1) | Etchant |
| Ti | HF | Pd | HNO₃ |
| Ti | HF | Ni or Co | S₂O₈²⁻ |
| Ti | HF | Cu | S₂O₈²⁻ |
| Ti | HF | Cr | Ce⁴⁺ |
| Al | OH⁻ | Ni or Co | S₂O₈²⁻ |
| Al | OH⁻ | Cu | S₂O₈²⁻ |
| C | O₂ plasma | Cr | Ce⁴⁺ |
| C | O₂ plasma | Ti | HF |
| C | O₂ plasma | Al | OH⁻ |

In one embodiment, SiO₂ or a high-k dielectric, such as Al₂O₃, for example, is used in each case for the dielectric layers 6.

The layer thicknesses of the electrically conductive layers lie for example within the range of between 10 nm and 1 gm, and for example within the range of between 10 nm and 100 nm, wherein the layer thicknesses of the layers composed of the first material 2 and the layer thicknesses of the layers composed of the second material 4 do not have to be identical to one another, and wherein the respective layer thicknesses of the layers composed of the first material 2 and the respective layer thicknesses of the layers composed of the second material 4 may deviate from one another.

The layer thicknesses of the dielectric layers 6 lie for example within the range of 1 nm to 100 nm, and for example within the range of 1 nm to 10 nm.

Furthermore, in one embodiment, as illustrated in FIG. 1, an optional dielectric layer may be applied as protection and insulation layer 8 or as etching stop layer onto the layer sequence formed or onto the topmost electrically conductive layer. The layer thickness of the protection and insulation layer 8 is 50 nm to 5 gm, by way of example. SiO₂, for example, may be used as material for the protection and insulation layer 8.

Finally, as illustrated in FIG. 1, a hard mask 10 is formed on the topmost electrically conductive layer or on the optional protection and insulation layer 8, the hard mask being composed of Si₃N₄, by way of example.

In one embodiment, to obtain the layer sequence 200 illustrated in FIG. 2, firstly the hard mask 10 is patterned at a first position in order to form a first trench 12 or a first via (=contact hole) in the layer sequence 200 by the patterned hard mask 10. As illustrated in FIG. 2, the first trench 12 extends through the entire layer sequence 200 and is formed for example perpendicular to at least a portion of the layer sequence 200. By way of example, the first trench 12 is formed by anisotropic etching for example by reactive ion etching (RIE) or by a sputtering etching (in this case, the hard mask 10 is to be chosen to be approximately twice as thick as the layer sequence 200 itself), the etching being effected anisotropically, i.e., almost exclusively in the vertical direction. The patterning of the hard mask 10 and the formation of the first trench 12 may, of course, also be effected in a single process.

Electrically conductive material for forming an electrically conductive connection element is introduced later into the first trench 12 formed in this way, with the result that the dimensions of the first trench 12 correspond to those of the connection element that is to be formed later. Thus, by way of example, the first trench 12 may be formed as a circular hole and the electrically conductive connection element may be formed in rod-type fashion.

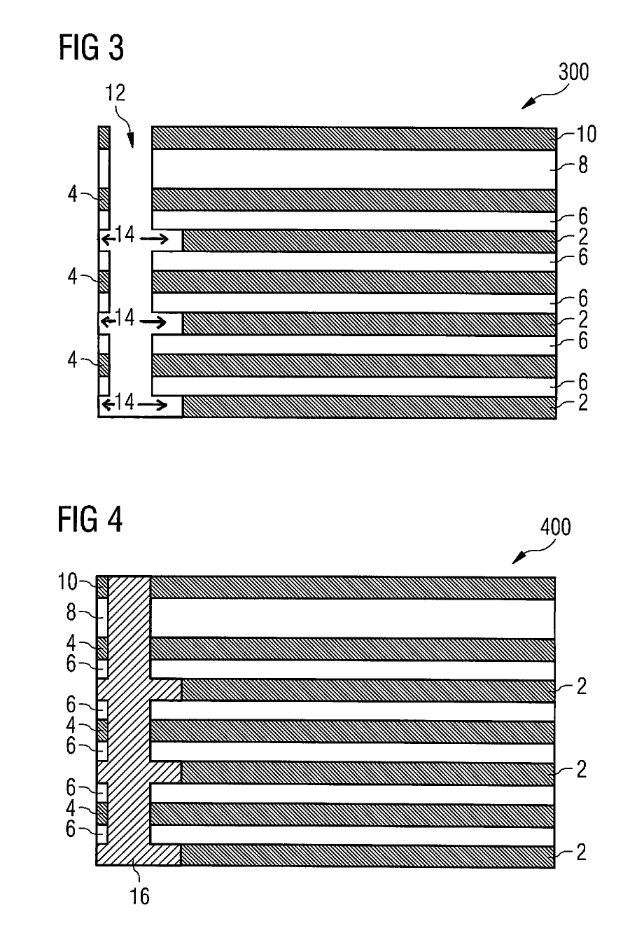

In one embodiment, to obtain the layer sequence 300 illustrated in FIG. 3, the layers composed of the first material 2 are patterned selectively with respect to the layers composed of the second material 4 in a first selective method by removing in each case that region/part of the layers composed of the first material 2 which directly adjoins the edge of the trench, with the result that the layers composed of the first material 2 are in each case driven back laterally in the direction of the first etching direction 14, marked by the arrows, and are no longer in contact with the peripheral side of the first trench 12. By way of example, the first selective method is an isotropic etching method, that is to say that the layers composed of the first material 2 are etched back in a lateral direction proceeding from the first trench 12 produced previously. The etching is effected selectively with respect to the second material 4 and for example selectively with respect to the dielectric of the dielectric layers 6. Selectively with respect to the second material 4 means that the layers composed of the first material 2 are etched, whereas the layers composed of the second material 4 are not attacked or etched, or are attacked or etched only with a considerably lower etching rate. By way of example, the layers composed of the first material 2 are etched in wet-chemical fashion. However, the etching may also be effected by any other wet etching method and/or dry etching method. The respective etchant for the selective etching of the first material 2 with a given material pairing can be gathered from table 1 (column 2 or 4). The depth of the etching or the length by which the layers composed of the first material 2 are etched back laterally is approximately 1 nm to 100 nm. If the first trench 12 or the via is formed as a circle in plan view, by way of example, then in plan view an annulus having the diameter of the via as internal diameter and a ring width of 1 nm to 100 nm is etched out from each layer composed of the first material 2.

In one embodiment, to obtain the layer sequence 400 illustrated in FIG. 4, a filling dielectric 16 is deposited as conformally as possible in the trench. By way of example, SiO₂ is introduced into the first trench 12, with the result that the etched-back regions of the layers composed of the first material 2 are at least partly filled with the filling dielectric 16. By way of example, filling dielectric 16 is simply introduced into the first trench 12 until the first trench 12 and the etched-back regions are completely filled with the filling dielectric 16. However, it is sufficient to introduce the filling dielectric 16 into the etched-back regions in such a way that the layers composed of the first material 2 are insulated from the first trench 12, into which later electrically conductive material for forming an electrically conductive connection element is introduced. On the other hand, by completely filling the first trench, it can be ensured that no etching solution penetrates into the first trench in subsequent etching processes, whereby the structure (comb structure) produced along the height/depth of the first trench is reliably maintained. This in turn enables efficient/economic work since the etchant can be fed onto the hard mask over an extensive area in a simple manner, for example, in the subsequent process/processes.

In one embodiment, to obtain the layer sequence 500 illustrated in FIG. 5, a second trench 18 or a second via is formed in the layer sequence 400 or 500. In this case, the procedure is analogous to the method process which leads from the layer sequence 100 to the layer sequence 200, that is to say that firstly the hard mask 10 is patterned at a second position, and the second trench 18 is formed by the patterned hard mask 1O. Like the first trench 12, the second trench 18 extends through the entire layer sequence 500 and is arranged/formed for example perpendicular to the layer sequence 500. The second trench 18 is likewise formed by anisotropic etching, by way of example.

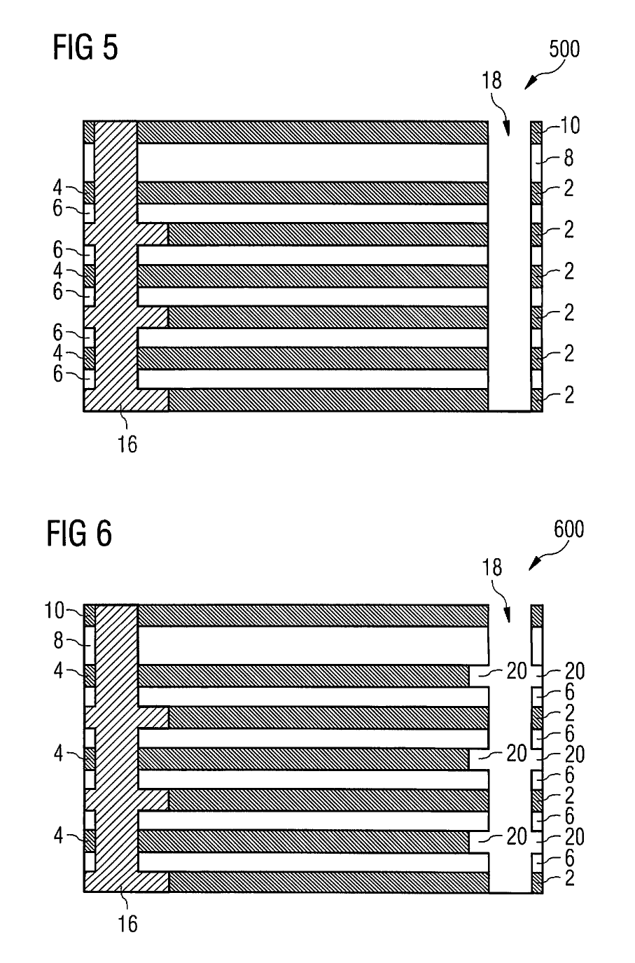

In one embodiment, to obtain the layer sequence 600 illustrated in FIG. 6, the layers composed of the second material 4 are patterned selectively with respect to the layers composed of the first material 2 in a second selective method by removing in each case that region/part of the layers composed of the second material 4 which adjoins the edge of the second trench 18, with the result that the layers composed of the second material 4 are in each case driven back laterally in the direction of the second etching direction 20, marked by the arrows, and are no longer in contact with the peripheral side of the second trench 18. By way of example, the layers composed of the second material 4 are etched back in a lateral direction in an isotropic etching method proceeding from the second trench 18 produced previously. The etching is effected selectively with respect to the first material 2 and for example selectively with respect to the dielectric of the dielectric layers 6. By way of example, the layers composed of the second material 4 are etched in wet-chemical fashion. However, the etching may also be effected by any other wet etching method and/or dry etching method. The respective etchant for the selective etching of the second material 4 with a given material pairing can be gathered from table 1 (column 2 or 4). The depth of the etching is approximately 1 nm to 100 nm.

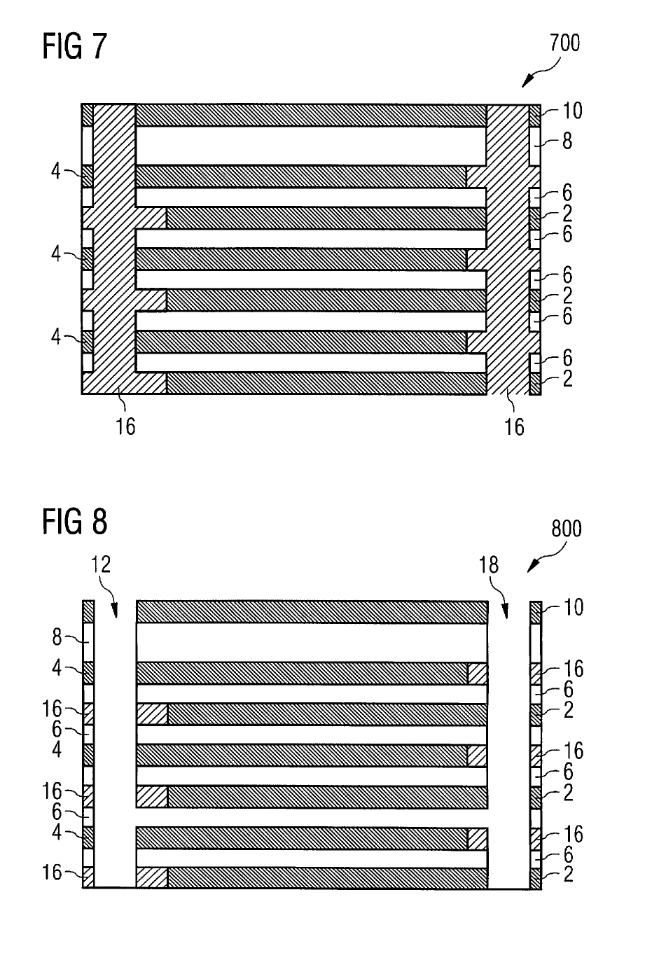

In one embodiment, to obtain the layer sequence 700 illustrated in FIG. 7, for example conformal filling dielectric 16 is introduced into the second trench 18 until the second trench 18 and the etched-back regions of the layers composed of the second material 4 are completely filled with the filling dielectric 16. However, it is sufficient in this case, too, to introduce filling dielectric 16 into the etched-back regions in such a way that the layers composed of the second material 4 are insulated from the second trench 18, into which later electrically conductive material for forming an electrically conductive connection element is introduced, which makes contact with the layers composed of the first material 2.

In one embodiment, to obtain the layer sequence 800 illustrated in FIG. 8, the filling dielectric 16 is removed within the first trench 12 and the second trench 18 by the patterned hard mask 10, in such a way that the first trench 12 and the second trench 18 are pulled back or uncovered, but the filling dielectric 16 is at least partly maintained within the respective etched-back regions, with the result that the layers composed of the first material 2 are furthermore insulated from the first trench 12 and the layers composed of the second material 4 are furthermore insulated from the second trench 18. By way of example, the filling dielectric 16 is etched anisotropically within the first trench 12 and the second trench 18. Anisotropically means that the etching direction is principally vertical and almost exclusively the filling dielectric 16 in the first trench 12 and the second trench 18 is etched.

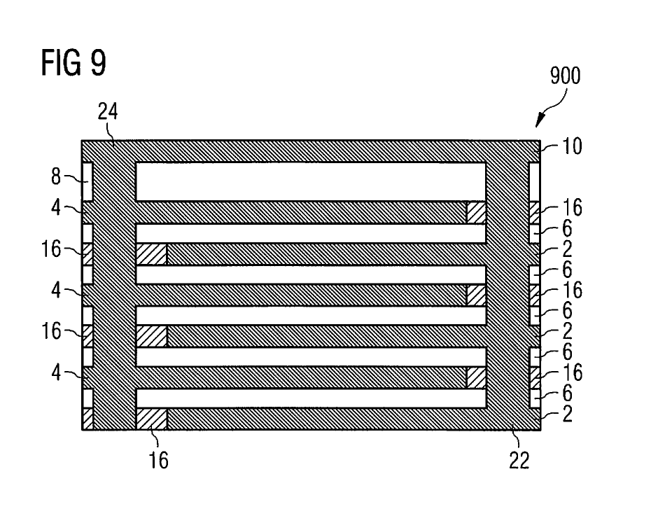

In one embodiment, to obtain the multilayer capacitance arrangement 900 illustrated in FIG. 9, which is produced in one embodiment, electrically conductive material is in each case introduced into the first trench 12 and the second trench 18, whereby a first electrically conductive connection element 22 for making contact with the electrically conductive layers composed of the first material 2 is formed in the second trench 18 and a second electrically conductive connection element 24 for making contact with the electrically conductive layers composed of the second material 4 is formed in the first trench 12. By way of example, W (tungsten) or Cu (copper) may be used as electrically conductive material. The formation of the first electrically conductive connection element 22 and of the second electrically conductive connection element 24 enables the layers composed of the first electrically conductive material 2 and the layers composed of the second electrically conductive material 4 to be in each case connected to one another and connected to a first electrical reference potential and respectively to a second electrical reference potential, whereby a capacitor is formed.

As an alternative to the selective etching method described above, the layers composed of the first material 2 and the layers composed of the second material 4 can in each case be patterned selectively with respect to one another by firstly oxidizing the first material 2 and the second material 4 selectively and partially, that is to say only on the outer side disposed toward the peripheral side of the respective trench, with the production of asacrificial oxide. Selective oxidation means that only one of the first material 2 and the second material 4 is oxidized and that the other of the first material 2 and the second material 4 is not oxidized. This is done by suitable selection of the first material 2 and the second material 4 and also by the setting of the operating parameters, such as e.g., the oxygen concentration or the oxygen pressure and the temperature. The oxide or sacrificial oxide of the first material 2 or of the second material 4 that is formed in this way can be etched by a suitable etchant which etches only the sacrificial oxide but does not attack the non-oxidized material.

Furthermore, additional trenches/vias can be formed in the layer sequence in order to form additional electrically conductive connection elements, so that the electrically conductive layers are contact-connected at a plurality of locations in each case. In this way, high-resistance materials or high-resistance metals may also be used for the electrically conductive layers.

A description is given below of a method for producing a multilayer capacitance arrangement in accordance with a second exemplary embodiment (not illustrated).

In this embodiment, the electrically conductive layers are in each case patterned directly after their formation in a separate method process. Thus, on the one hand, significantly more method processes are necessary for producing the multilayer capacitance arrangement, and on the other hand, just a single electrically conductive material component can be used and does not have to be etched selectively.

A first electrically conductive layer is formed on or above the at least one metallization level. Optionally, firstly a protection and insulation layer may be deposited on or above the at least one metallization level, on which layer the first electrically conductive layer is then formed.

A hard mask is then formed on the first electrically conductive layer, the hard mask being patterned at a first position. As an alternative, the hard mask can be deposited directly with formation of a structure on the first electrically conductive layer, so that the method process of patterning of the hard mask can be obviated.

The first electrically conductive layer is thereupon patterned by the patterned hard mask at the first position and the hard mask is removed.

A filling dielectric is then introduced into the structure produced in the first electrically conductive layer and a first dielectric layer is formed on the first electrically conductive layer and on the structure filled with filling dielectric.

A second electrically conductive layer is then applied to the first dielectric layer and a hard mask is deposited on the second electrically conductive layer, the hard mask being patterned at a second position. By the patterned hard mask, the second electrically conductive layer is patterned at the second position, whereupon the hard mask is removed. The filling dielectric is then introduced into the structure produced in the second electrically conductive layer and a second dielectric layer is deposited on the second electrically conductive layer and on the structure filled with the filling dielectric.

A third electrically conductive layer is formed on the second dielectric layer, on which electrically conductive layer a hard mask is once again deposited, which is patterned at the first position and by which the third electrically conductive layer is patterned at the first position. The hard mask is removed and the filling dielectric is introduced into the structure produced in the third electrically conductive layer.

For alternately connecting the electrically conductive layers to a first electrical reference potential and a second electrical reference potential, respectively, it is possible to form a first electrically conductive connection element, which makes contact with the first electrically conductive layer and the third electrically conductive layer, and a second electrically conductive connection element, which makes contact with the second electrically conductive layer.

The first electrically conductive connection element and the second electrically conductive connection element are formed for example in each case perpendicular to at least one portion of the electrically conductive layers.

If the electrically conductive layers are in each case patterned on the peripheral side, for example, that is to say that the structure formed at the first position and at the second position adjoins the peripheral side of the respective layer, the first electrically conductive connection element and the second electrically conductive connection element may in each case be formed alongside or adjoining the electrically conductive layers, wherein the first electrically conductive connection element adjoins the second position and the second electrically conductive connection element adjoins the first position.

As an alternative, the electrically conductive layers can be patterned in the interior, for example by formation of a circular hole within or in the interior of the electrically conductive layers at the first position and at the second position. In this case, at the first position and at the second position, after the formation and patterning of the electrically conductive layers, a contact hole/trench is in each case formed through the layer arrangement, where the diameter of the contact hole, given an identical midpoint, is smaller than the diameter of the circular hole or the structure. The two contact holes can then be filled with electrically conductive material.

Although the method in accordance with the second exemplary embodiment has been described with regard to a multilayer capacitance arrangement having only three electrically conductive layers, it is possible to form, above the third electrically conductive layer, further electrically conductive layers with in each case a dielectric layer between two electrically conductive layers, in which case the electrically conductive layers are respectively patterned directly after their formation by a hard mask or an alternative method alternately at the first position and at the second position.

The material used for the filling dielectric and the dielectric layers may be the same material or a different material and, for example, SiO₂ or a high-k dielectric.

The material for the electrically conductive layers can be selected from table 1, for example, but is not restricted to the materials. In addition, a possible etchant when using a corresponding material can be gathered from table 1.

The layer thicknesses specified for the first exemplary embodiment also apply to the second exemplary embodiment of the invention.

Although the invention has been illustrated and described primarily in connection with specific exemplary embodiments, it should be understood by those skilled in the art that diverse changes can be made in the configuration and the details thereof without departing from the essence and scope of the invention as defined by the subsequent claims. Therefore, the scope of the invention is determined by the attached claims, and the intention is for all variations which lie within the scope of the meaning and the range of equivalence of the claims to be encompassed by the claims.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit having a multilayer capacitor arrangement comprising:
a substrate with electronic components integrated therein;
at least one metallization level arranged above the substrate and having interconnects for connecting the electronic components;
a first electrically conductive layer above the at least one metallization level;
a first dielectric layer on or above the first electrically conductive layer;
a second electrically conductive layer on or above the first dielectric layer;
a second dielectric layer on or above the second electrically conductive layer; and
a third electrically conductive layer on or above the second dielectric layer.

2. The integrated circuit of claim 1, comprising:
an additional electrically conductive layer in a direction substantially orthogonal to the first electrically conductive layer.

3. The integrated circuit of claim 1, comprising:
at least one additional electrically conductive layer in a vertical direction relative to the first dielectrics layer in a horizontal direction.

4. The integrated circuit of claim 1, comprising:
a plurality of electrically conductive layers insulated from one another, in a direction substantially orthogonal to the first or second electrically conductive layer.

5. The integrated circuit of claim 1, comprising:
the first dielectric layer is made of a high-k dielectric.

6. The integrated circuit of claim 1, comprising:
the first dielectric layer is made of silicon dioxide.

7. The integrated circuit of claim 1, wherein the first electrically conductive layer, the second electrically conductive layer and the third electrically conductive layer are alternately connected to a first potential and a second potential.

8. An integrated circuit having a multilayer capacitance arrangement, comprising:
a substrate with electronic components integrated therein;
at least one metallization level arranged above the substrate and having interconnects for connecting the electronic components;
a first electrically conductive layer above the at least one metallization level;
a first dielectric layer on or above the first electrically conductive layer;
a second electrically conductive layer on or above the first dielectric layer;
a second dielectric layer on or above the second electrically conductive layer; and
a third electrically conductive layer on or above the second dielectric layer;
a first electrically conductive connection element, which is electrically connected to the first electrically conductive layer and the third electrically conductive layer; and
a second electrically conductive connection element, which is electrically connected to the second electrically conductive layer.

9. The integrated circuit of claim 8, comprising:
wherein the first electrically conductive layer is made of a first material, the second electrically conductive layer is made of a second material and the third electrically conductive layer is made of the first material.

10. The integrated circuit of claim 9, comprising:
wherein the first material and the second material can be etched selectively with respect to one another and/or can be oxidized selectively with respect to one another.

11. The integrated circuit of claim 8, comprising:
wherein the first electrically conductive connection element is a second trench filled with electrically conductive material and extends through the electrically conductive layers at a first position, and wherein the second electrically conductive connection element is a first trench filled with electrically conductive material and extends through the electrically conductive layers at a second position.

12. The integrated circuit of claim 8, comprising:
wherein the first electrically conductive layer and the third electrically conductive layer are etched back laterally relative to the edge of the first trench and are electrically insulated from the second connection element by a filling dielectric that is at least partly introduced into the etched-back regions, and wherein the second electrically conductive layer is etched back laterally relative to the edge of the second trench and is electrically insulated from the first connection element by a filling dielectric that is at least partly introduced into the etched-back region.

13. The integrated circuit of claim 8, comprising wherein the first electrically conductive connection element and the second electrically conductive connection element in each case extend perpendicular to at least one portion of the electrically conductive layers.

14. The integrated circuit of claim 8, comprising wherein one of the first material and the second material is carbon and the other of the first material and the second material is chromium or titanium or aluminum.

15. The integrated circuit of claim 8, comprising wherein one of the first material and the second material is aluminum and the other of the first material and the second material is nickel or cobalt or copper.

16. The integrated circuit of claim 8, comprising wherein one of the first material and the second material is titanium and the other of the first material and the second material is palladium or nickel or cobalt or copper or chromium.

17. The integrated circuit of claim 8, comprising wherein the dielectric of the first dielectric layer and of the second dielectric layer is in each case a high-k dielectric or SiO₂.

18. A method for producing an integrated circuit having a multilayer capacitance arrangement, comprising:
forming a first electrically conductive layer above at least one metallization level arranged above a substrate with electronic components integrated therein and having interconnects for connecting the electronic components;
forming a first dielectric layer on or above the first electrically conductive layer;
forming a second electrically conductive layer on or above the first dielectric layer;
forming a second dielectric layer on or above the second electrically conductive layer; and
forming a third electrically conductive layer on or above the second dielectric layer.

19. The method of claim 18, comprising:
using a first material for the first electrically conductive layer, and using a second material, which is different from the first material, for the second electrically conductive layer and the first material is used for the third electrically conductive layer, wherein the first material and the second material are selected in such a way that the first material and the second material can be etched selectively with respect to one another and/or the first material and the second material can be oxidized selectively with respect to one another;

20. The method of claim 18, comprising:
etching a first trench and a second trench through the electrically conductive layers, the first material is etched selectively with respect to the second material, wherein the first electrically conductive layer and the third electrically conductive layer are etched back laterally proceeding from the first trench, the second material is etched selectively with respect to the first material, wherein the second electrically conductive layer is etched back laterally proceeding from the second trench, the etched-back regions of the electrically conductive layers are at least partly filled with a filling dielectric, and electrically conductive material is introduced into the first trench and to the second trench.

21. The method of claim 18, comprising connecting the first electrically conductive layer and the third electrically conductive layer to a first electrical reference potential, and connecting the second electrically conductive layer to a second electrical reference potential.

22. The method of claim 18, comprising wherein the at least partial filling of the etched-back regions is effected by:
introducing the filling dielectric into in each case the first trench and the second trench and also into the respective etched-back regions of the electrically conductive layers in such a way that, in the etched-back regions, at least the region directly adjoining the electrically conductive layer is filled with the filling dielectric; and
uncovering the first trench and the second trench again by etching in such a way that, within the etched-back regions, the filling dielectric is maintained at least in the region directly adjoining the electrically conductive layer.

23. The method of claim 18, comprising using titanium for one of the first material and the second material and using palladium or nickel or cobalt or copper or chromium for the other of the first material and the second material.

24. The method of claim 23, comprising:
selectively etching titanium with respect to the corresponding other material by hydrofluoric acid; and
selectively etching palladium with respect to titanium by nitric acid, nickel, cobalt or copper is etched selectively with respect to titanium by a solution containing peroxodisulfate ions and chromium is etched selectively with respect to titanium by a cerium(IV) solution.

25. The method of claim 18, comprising using aluminum for one of the first material and the second material and using nickel or cobalt or copper for the other of the first material and the second material.

26. The method of claim 25, comprising:
selectively etching aluminum with respect to the corresponding other material by a solution containing hydroxide ions; and
selectively etching nickel, cobalt or copper with respect to aluminum by a solution containing peroxodisulfate ions.

27. The method of claim 18, comprising using carbon for one of the first material and the second material and using chromium or titanium or aluminum for the other of the first material and the second material.

28. The method of claim 27, comprising:
selectively etching carbon with respect to the corresponding other material by an ° 2 plasma; and
selectively etching chromium with respect to carbon by a cerium(IV) solution, titanium is etched selectively with respect to carbon by hydrofluoric acid and aluminum is etched selectively with respect to carbon by a solution containing hydroxide ions.

29. The method of claim 18, comprising etching the first trench and the second trench using a hard mask that is formed on or above the third electrically conductive layer and is patterned.

30. An integrated circuit having a multilayer capacitor arrangement comprising:
a substrate with electronic components integrated therein;
means for providing at least one metallization level arranged above the substrate and having interconnects for connecting the electronic components;
means for providing a first electrically conductive layer above the at least one metallization level means;
a first dielectric layer on or above the first electrically conductive layer means;
means for providing a second electrically conductive layer on or above the first dielectric layer;
a second dielectric layer on or above the second electrically conductive layer means; and
means for providing a third electrically conductive layer on or above the second dielectric layer.
